(19) United States
(12) Patent Application Publication
(10) Pub. No.: US 2026/0088792 A1
(43) Pub. Date: Mar. 26, 2026

(54) ELECTRICAL DEVICE LINE FILTER

(71) Applicant: Applied Materials, Inc., Santa Clara, CA (US)

(72) Inventors: Yue GUO, Redwood City, CA (US); Denis Martin KOOSAU, Sunnyvale, CA (US); Shreeram Jyoti DASH, San Jose, CA (US); Kartik RAMASWAMY, San Jose, CA (US)

(21) Appl. No.: 18/895,466

(22) Filed: Sep. 25, 2024

(51) Int. Cl. H03H 7/01; H01J 37/32

(52) U.S. Cl. CPC H03H 7/0115; H01J 37/32724

(57) ABSTRACT

The present disclosure describes a filter assembly for a heater line of a processing chamber. The filter assembly includes a first impedance producing element, a first air core inductor, and a second air core inductor. The first impedance producing element includes a first conductive lead and a second conductive lead wound around a first toroid shaped core. A first end of the first conductive lead and a first end of the second conductive lead are coupled to an output of an electric device. The first air core inductor is electrically connected with the first conductive lead. The second air core inductor is electrically connected with the second conductive lead.

### FIELD

Embodiments described herein generally relate to plasma processing chambers used in semiconductor manufacturing.

### BACKGROUND

### DESCRIPTION OF THE RELATED ART

Reliably producing high aspect ratio features is one of the key technology challenges for the next generation of very large scale integration (VLSI) and ultra large scale integration (ULSI) of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in an RIE processing chamber and ions from the plasma are accelerated towards a surface of a substrate to form openings in a material layer disposed beneath a mask layer formed on the surface of the substrate.

A challenge for current plasma processing chambers and processes includes controlling critical dimension uniformity during plasma processing, which may be achieved by heating the electrostatic chuck (ESC) assembly in a controlled way. A multi-zone heating assembly embedded in a dielectric material is used to heat the electrostatic chuck assembly. A typical Reactive Ion Etch (RIE) plasma processing chamber includes a radio frequency (RF) bias generator, which supplies an RF voltage to a “power electrode,” a metal baseplate embedded into the substrate support assembly, more commonly referred to as the “cathode.” The power RF biased electrode is capacitively coupled to the multi-zone electrostatic chuck heating assembly via a layer of dielectric material (e.g., ceramic material), which is a part of the ESC assembly. The strong capacitive coupling between power electrode and the multi-zone electrostatic chuck heating provides a path for flow of significant RF currents to ground, which results in loading of the RF biased waveform and loss of RF power. An undesirably large flow of RF current from the RF driven components to the grounded hardware components can cause many undesirable effects, which include a reduction in the amount of RF power that can effectively be provided to the power electrode (e.g., reduces the RF transfer efficiency), can create personnel safety issues and can cause unwanted damage to ancillary electrical and hardware components. The ability to prevent these undesirable effects becomes even harder to accomplish when the RF power provided to the power electrode includes a broad range of RF frequencies. Most traditional RF filtering techniques are tuned to block the narrow range of frequencies that are provided from the RF power supply to prevent the generated RF energy from damaging external and ancillary electrical components that are connected to the RF driven circuit. As semiconductor device aspect ratios become higher, higher ion energy is used to etch these features. To achieve higher ion energy, the trend is to move to lower frequency and higher power, which makes filter design even more challenging. In particular, a shaped DC pulse can be used, which is low frequency and has a broad frequency spectrum, which is difficult to filter using conventional filtering designs.

For example, some existing processing chambers include a filter assembly that uses common mode choke filters to block RF power from the power electrode. The common mode choke filters, however, are not sufficient to block the RF power at lower frequencies and higher power, such as shaped DC pulses. As a result, the RF power leaks into the heating assembly and couples into the electrical line powering the heating assembly, which causes that electrical line to increase in temperature, damaging the electrical line and the power supply.

Therefore, there is need for a filtering assembly design that solves the problems described above.

### SUMMARY

The present disclosure describes a filter assembly for a heater line of a processing chamber. According to an embodiment, a filter assembly includes a first impedance producing element, a first air core inductor, and a second air core inductor. The first impedance producing element includes a first conductive lead and a second conductive lead wound around a first toroid shaped core. A first end of the first conductive lead and a first end of the second conductive lead are coupled to an output of an electric device. The first air core inductor is electrically connected with the first conductive lead. The second air core inductor is electrically connected with the second conductive lead.

According to another embodiment, a method includes directing a first electrical signal from a power supply to a heating element of a heater assembly of a processing chamber and receiving a second electrical signal at the heating element. The method also includes filtering, using a first air core inductor and a second air core inductor electrically connected to the heater element and the power supply, the second electrical signal to prevent a portion of the second electrical signal from reaching the power supply.

According to another embodiment, a processing chamber includes a substrate support, an electrode within the substrate support, a heater element of a heater assembly within the substrate support, and a filter assembly connected to the heater element. The filter assembly includes a first impedance producing element, a first air core inductor, and a second air core inductor. The first impedance producing element includes a first conductive lead and a second conductive lead wound around a first toroid shaped core. The first air core inductor is electrically connected with the first conductive lead. The second air core inductor is electrically connected with the second conductive lead.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of an example processing chamber, according to one embodiment.

FIGS. 2A through 2L illustrate example filter assemblies of the processing chamber of FIG. 1, according to one embodiment.

FIG. 3 illustrates an example impedance producing element of the filter assemblies of FIGS. 2A through 2L, according to one embodiment.

FIG. 4 is a flowchart of an example method performed by the processing chamber of FIG. 1, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure describes a filter assembly for an electrical line of an electric device of a processing chamber. The filter assembly uses a hybrid filter design that includes one or more common mode choke filters and one or more filters using air core inductors. The air core inductors provide high impedance for low frequency pulsed direct current (DC) signals and/or low frequency RF signals, such as the fundamental frequency for DC shaped pulses and its harmonics. The common mode choke filters and the filters using air core inductors may be electrically connected to each other between a device of the electric device, such as a power supply coupled to a heater assembly, and an electrode or element used within the processing chamber.

In some embodiments, the filter assembly provides certain technical advantages. For example, the filter assembly blocks low frequency pulsed DC signals and low frequency RF signals from coupling into the electrical line, such as a heater line. As a result, the filter assembly reduces the temperature of the electrical line relative to some existing processing chambers. Moreover, the filter assembly reduces damage to the electric device, which can include a heater line and power supply used to deliver power to the heater line, relative to some existing processing chambers. While the disclosure provided herein primarily discloses the use of a filter assembly in conjunction with a heater and/or components of a heater assembly, one skilled in the art will appreciate that the various embodiments disclosed herein can be used to electrically isolate other types of electrical circuits or electrical assemblies that are exposed to various RF and/or pulsed DC signals delivered to portions of a processing chamber during processing.

Embodiments described herein are applicable for use in all types of plasma assisted or plasma enhanced processing chambers and also for methods of plasma assisted or plasma enhanced processing of a substrate. More specifically, embodiments of this disclosure include a broadband frequency filter assembly, also referred to herein as a filter assembly, that is configured to reduce and/or prevent leakage currents from being transferred from one or more driven components to a ground through other electrical components that are directly or indirectly electrically coupled to the driven components and ground.

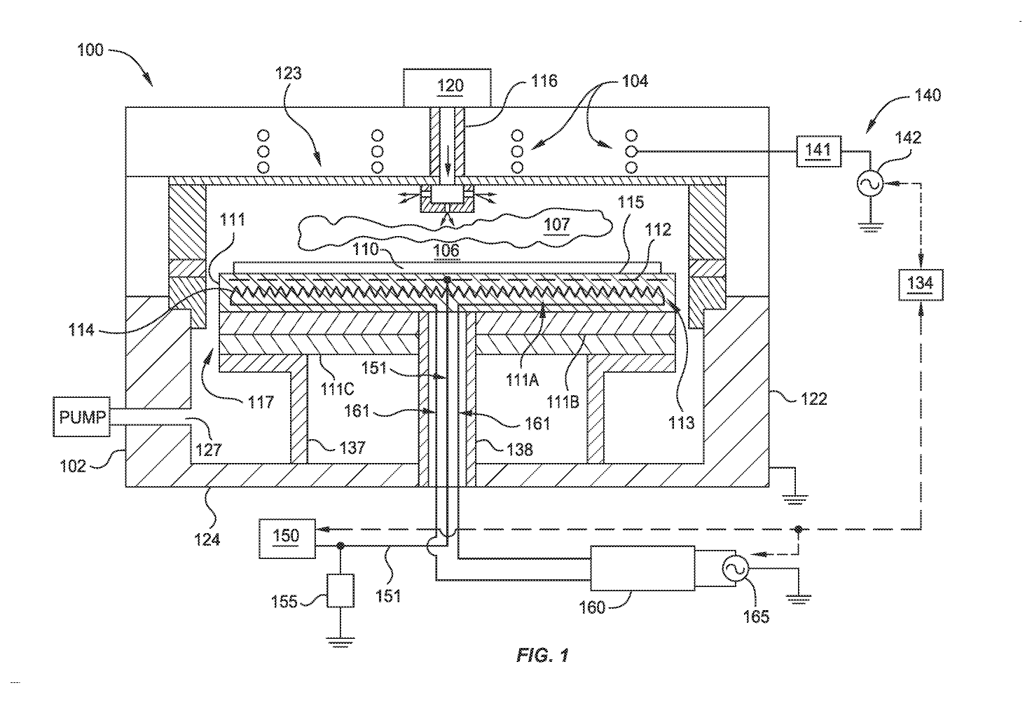

FIG. 1 is a schematic cross-sectional view of a processing chamber 100 configured to perform a plasma process within a processing volume 106 of the process chamber 100 by use of a source assembly 140, according to one embodiment. In this embodiment, the processing chamber 100 is a plasma processing chamber, such as a reactive ion etch (RIE) plasma chamber. In some other embodiments, the processing chamber is a plasma-enhanced deposition chamber, for example a plasma-enhanced chemical vapor deposition (PECVD) chamber, a plasma enhanced physical vapor deposition (PEPVD) chamber, or a plasma-enhanced atomic layer deposition (PEALD) chamber. In some other embodiments, the processing chamber is a plasma treatment chamber, or a plasma based ion implant chamber, for example a plasma doping (PLAD) chamber. As shown in FIG. 1, the processing chamber 100 includes a source assembly 140 that includes an inductively coupled plasma (ICP) source electrically coupled to a radio frequency (RF) power supply 142 through an RF matching circuit 141. In other embodiments, the source assembly 140 is a capacitively coupled plasma (CCP) source, such as a source electrode (not shown) disposed in the processing volume 106 facing the substrate support 111, wherein the source electrode is electrically coupled to an RF power supply (not shown).

The processing chamber 100 includes a chamber body 102 which includes a chamber lid 123, one or more sidewalls 122, and a chamber base 124 which define a processing volume 106. A gas inlet 116 disposed through the chamber lid 123 is used to provide one or more processing gases to the processing volume 106 from a processing gas source 120 in fluid communication therewith. The power supply 142 is configured to ignite and maintain a processing plasma 107 from the processing gases using one or more inductive coils 104 disposed proximate to the chamber lid 123 outside of the processing volume 106. The processing volume 106 is fluidly coupled to one or more dedicated vacuum pumps, through a vacuum outlet 127, which maintain the processing volume 106 at sub-atmospheric conditions and evacuate processing gases and/or other gases therefrom. A substrate support assembly 117 is disposed in the processing volume 106 and on a support shaft 138 sealingly extending through the chamber base 124.

The substrate 110 is loaded into and removed from the processing volume 106 through an opening (not shown) in one of the one or more sidewalls 122, which is sealed with a door or a valve (not shown) during plasma processing of the substrate 110. Herein, the substrate 110 is transferred to and from a receiving surface 115 (e.g., substrate supporting surface) of the substrate support 111, which can include an ESC substrate support 111A using a lift pin system (not shown).

The substrate support 111 includes a support base 111B and the ESC substrate support 111A that is thermally coupled to and disposed on the support base 111B. The support base 111B is electrically isolated from the chamber base 124 by an insulator plate 111C and a ground plate 137 that is interposed between the insulator plate 111C and the chamber base 124. Typically, the support base 111B is used to regulate the temperatures of the ESC substrate support 111A and the substrate 110 disposed on the ESC substrate support 111A during substrate processing. In some embodiments, the support base 111B includes one or more cooling channels (not shown) disposed therein that are fluidly coupled to, and in fluid communication with, a coolant source (not shown), such as a refrigerant source or water source having relatively high electrical resistance. Herein, the support base 111B is formed of a corrosion resistant thermally conductive material, such as a corrosion resistant metal, for example aluminum, aluminum alloy, or stainless steel and is coupled to the substrate support with an adhesive or by mechanical means.

Typically, the ESC substrate support 111A is formed of a dielectric material, such as a bulk sintered ceramic material, such as a corrosion resistant metal oxide or metal nitride material, for example aluminum oxide (Al₂O₃), aluminum nitride (AlN), titanium oxide (TiO), titanium nitride (TiN), yttrium oxide (Y₂O₃), mixtures thereof, or combinations thereof. In some embodiments, the ESC substrate support 111A further includes a biasing electrode 112 embedded in the dielectric material. In one configuration, the biasing electrode 112 is a chucking pole used to secure (chuck) the substrate 110 to the receiving surface 115 of the ESC substrate support 111A and to bias the substrate 110 with respect to the processing plasma 107. Typically, the biasing electrode 112 is formed of one or more electrically conductive parts, such as one or more metal meshes, foils, plates, or combinations thereof. Herein, the biasing electrode 112 is electrically coupled to a high voltage module 155 which provides a chucking voltage thereto, such as static DC voltage between about -5000 V and about 5000 V, using an electrical conductor, such as the transmission line 151.

The ESC substrate support 111A includes a heater element 113 (which may also be referred to as a heater), such as a resistive heating element, embedded in the dielectric material of the ESC substrate support 111A. The heater element 113 is used to generate heat within the ESC substrate support 111A due to resistive heating created by the delivery of AC power through one or more conductive elements 114, which are embedded within the material used to form the ESC substrate support 111A, by use of an AC power supply 165. In one embodiment, the one or more conductive elements 114 are spaced a distance from the biasing electrode 112, and thus are not directly connected to the biasing electrode 112. The heater element 113 may include a plurality of heating zones formed using multiple conductive elements 114. Each heating zone may generate and apply a different amount of heat to a different portion of the ESC substrate support 11A and/or the substrate 110.

A filter assembly 160 is disposed between the AC power supply 165 and the one or more conductive elements 114 to prevent RF leakage from the biasing electrode 112 to the one or more conductive elements 114 from flowing into the AC power supply 165 and damaging its internal components and/or creating an unsafe condition for a user of the processing tool.

The biasing electrode 112 is spaced apart from the substrate receiving surface 115 of the ESC substrate support 111A, and thus from the substrate 110, by a layer of dielectric material of the ESC substrate support 111A. Typically, the layer of dielectric material has a thickness between about 0.1 mm and about 1 mm, such as between about 0.1 mm and about 0.5 mm, for example about 0.3 mm. Herein, the biasing electrode 112 is electrically coupled to the power generator 150 using the external conductor, such as the transmission line 151. The power generator 150 can be a direct current (DC) power generator, a low frequency RF power generator, or a shaped pulsed DC bias power generator. The dielectric material and layer thickness formed between biasing electrode 112 and the substrate receiving surface 115 can be selected so that the capacitance of the layer of dielectric material is between about 5 nF and about 12 nF, such as between about 7 and about 10 nF, for example.

The processing chamber 100 further includes a system controller 134. The system controller 134 herein includes a central processing unit (CPU), a memory, and support circuits. The system controller 134 is used to control the process sequence used to process the substrate 110. The CPU is a general purpose computer processor configured for use in an industrial setting for controlling processing chamber and sub-processors related thereto. The memory described herein may include random access memory, read only memory, floppy or hard disk drive, or other suitable forms of digital storage, local or remote. The support circuits are conventionally coupled to the CPU and comprise cache, clock circuits, input/output subsystems, power supplies, and the like, and combinations thereof. Software instructions and data can be coded and stored within the memory for instructing a processor within the CPU. A program (or computer instructions) readable by the system controller 134 determines which tasks are performable by the components in the processing chamber 100. Preferably, the program, which is readable by the system controller 134, includes code, which when executed by the processor, perform tasks relating to the monitoring and execution of the electrode biasing scheme described herein. The program will include instructions that are used to control the various hardware and electrical components within the processing chamber 100 to perform the various process tasks and various process sequences used to implement the electrode biasing scheme described herein.

The CPU is any electronic circuitry, including, but not limited to one or a combination of microprocessors, microcontrollers, application specific integrated circuits (ASIC), application specific instruction set processor (ASIP), and/or state machines, that communicatively couples to the memory. The CPU may be 8-bit, 16-bit, 32-bit, 64-bit or of any other suitable architecture. The CPU may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The CPU may include other hardware that operates software to control and process information. The CPU executes software stored on the memory to perform any of the functions described herein. The CPU controls the operation and administration of the processing chamber 100 by processing information (e.g., information received from sensors and/or the memory). The CPU is not limited to a single processing device and may encompass multiple processing devices contained in the same device or computer or distributed across multiple devices or computers. The CPU is considered to perform a set of functions or actions if the multiple processing devices collectively perform the set of functions or actions, even if different processing devices perform different functions or actions in the set.

The memory may store, either permanently or temporarily, data, operational software, or other information for the CPU. The memory may include any one or a combination of volatile or non-volatile local or remote devices suitable for storing information. For example, the memory may include random access memory (RAM), read only memory (ROM), magnetic storage devices, optical storage devices, or any other suitable information storage device or a combination of these devices. The software represents any suitable set of instructions, logic, or code embodied in a computer-readable storage medium. For example, the software may be embodied in the memory, a disk, a CD, or a flash drive. In particular embodiments, the software may include an application executable by the CPU to perform one or more of the functions described herein. The memory is not limited to a single memory and may encompass multiple memories contained in the same device or computer or distributed across multiple devices or computers. The memory is considered to store a set of data, operational software, or information if the multiple memories collectively store the set of data, operational software, or information, even if different memories store different portions of the data, operational software, or information in the set.

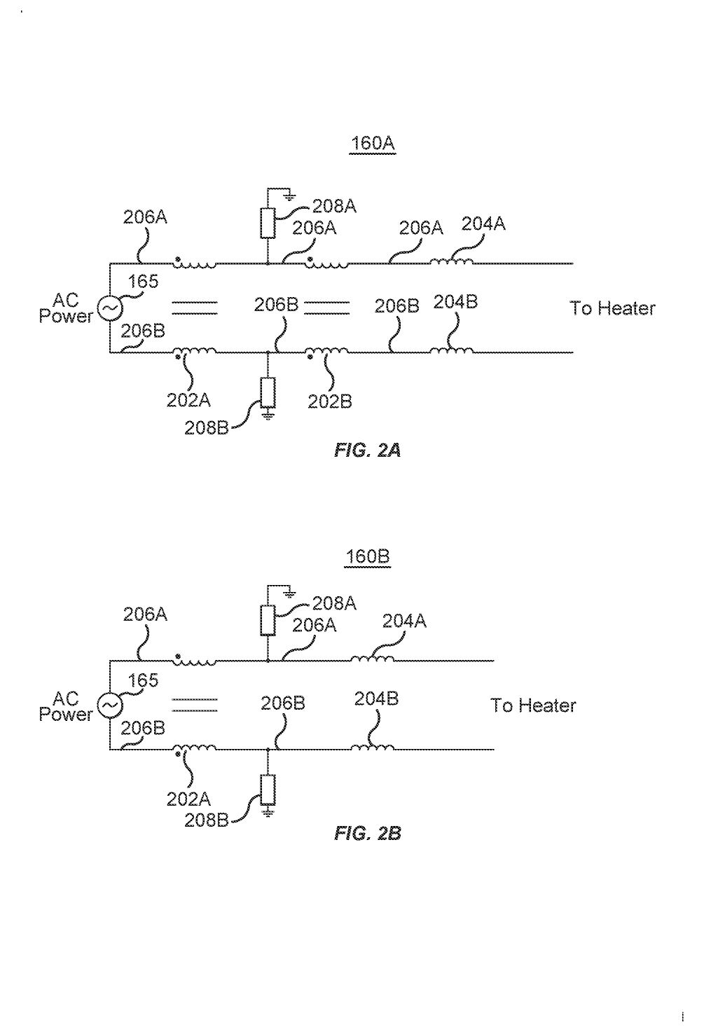

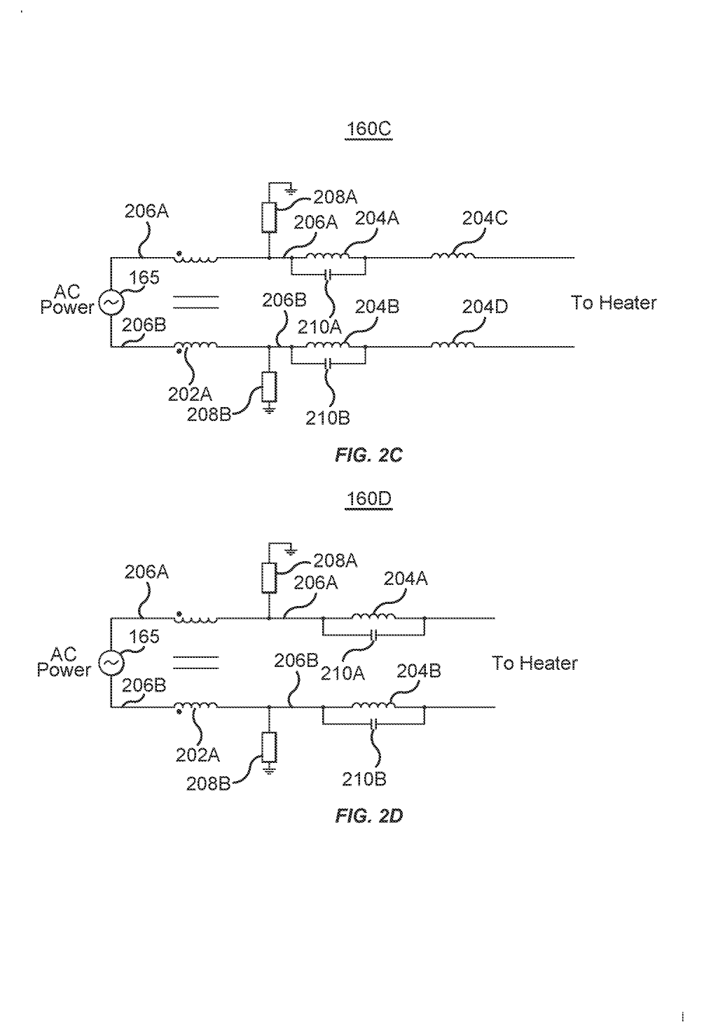

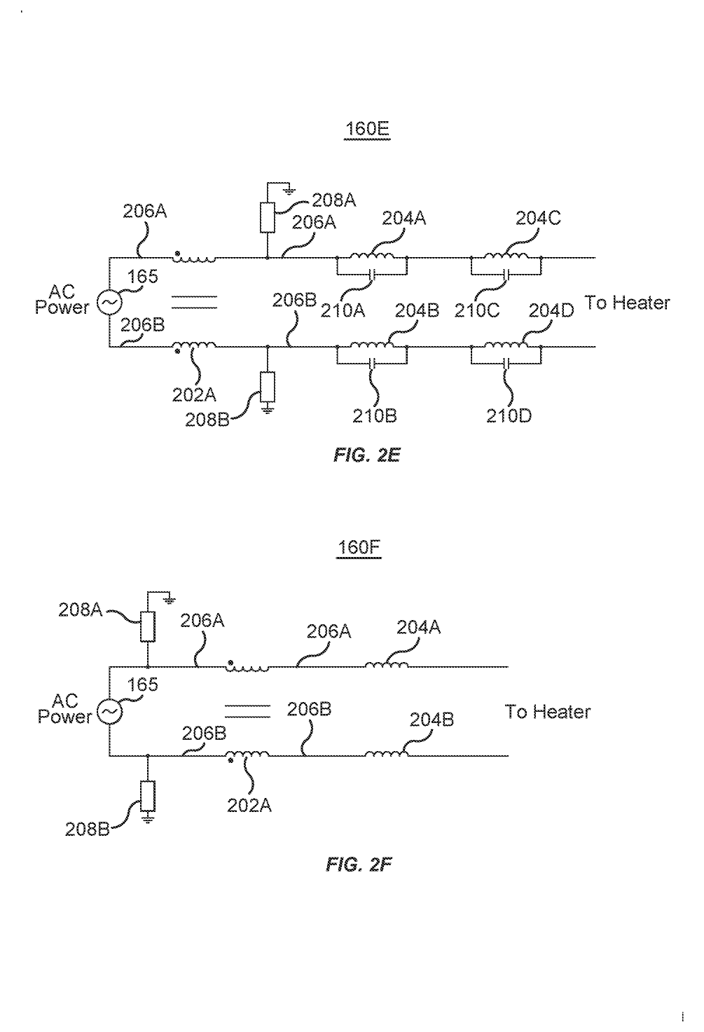

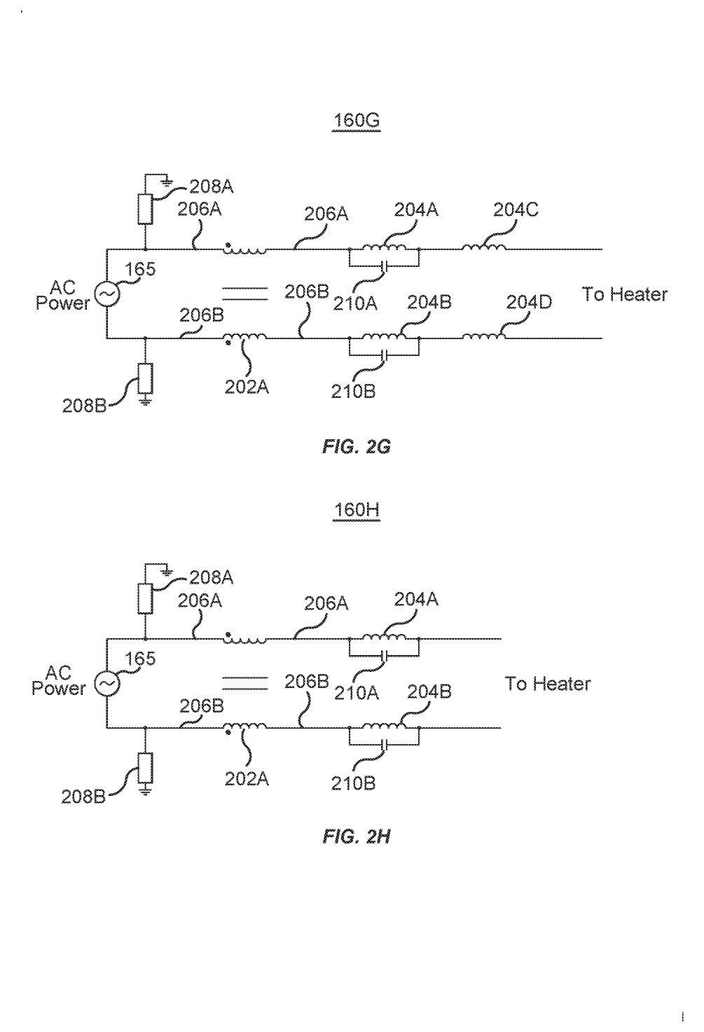

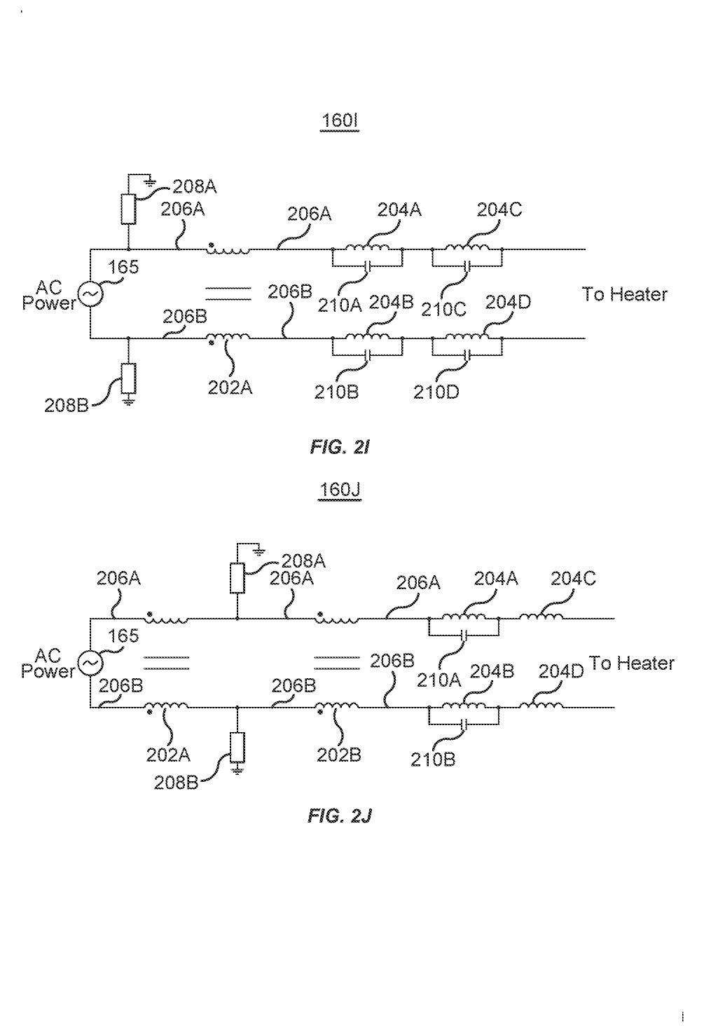

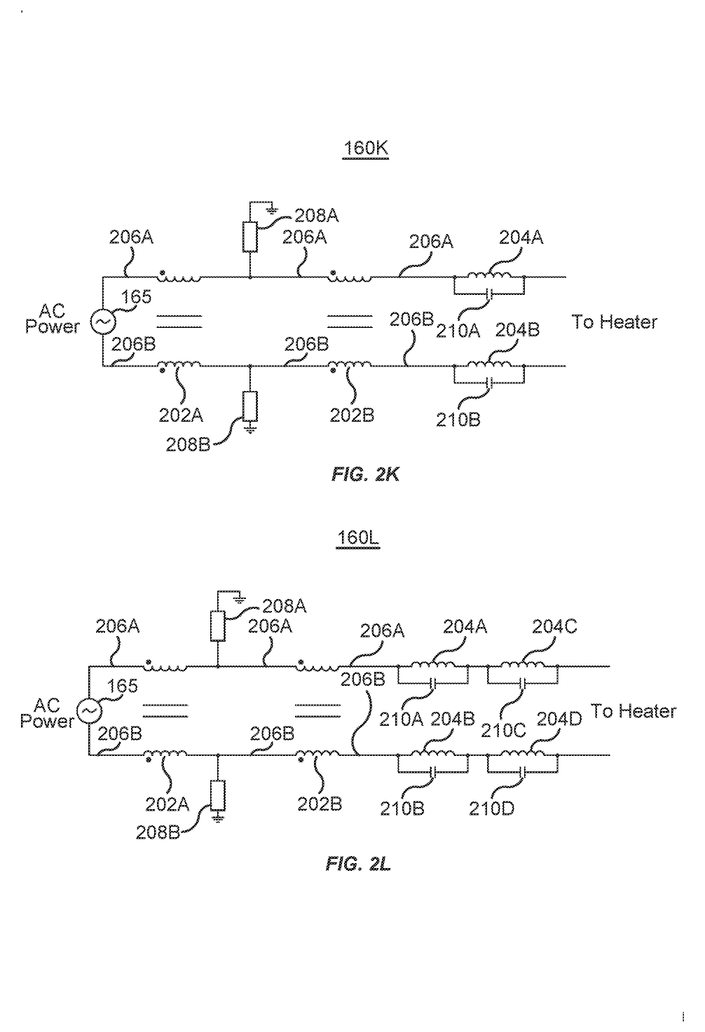

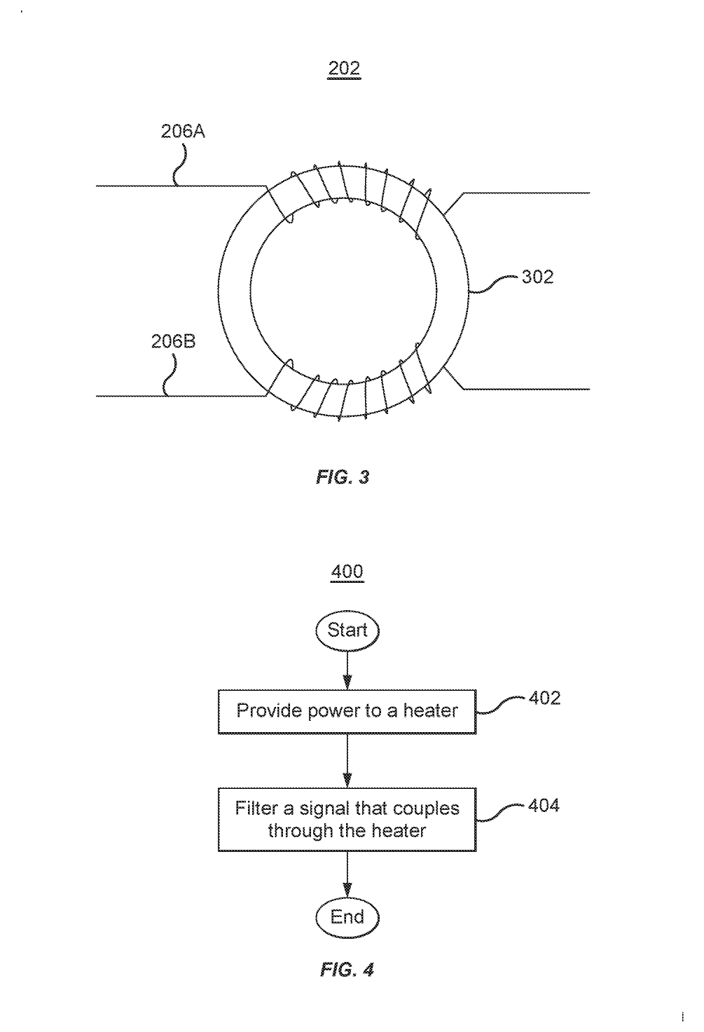

FIG. 2A through FIG. 2L illustrate example filter assemblies of the processing chamber 100 of FIG. 1. Generally, each of the filter assemblies shown in FIG. 2A through FIG. 2L include at least one impedance producing element (e.g., a common mode choke filter) and at least two air core inductors. These filter assemblies may be positioned between a power supply and a heater for the processing chamber 100. The filter assemblies may present an impedance (e.g., approximately 2000 Ohms) to low frequency RF signals and/or pulsed DC signals (e.g., asymmetric DC shaped pulses), which effectively blocks these signals from leaking from the heater to the power supply. As a result, the filter assemblies reduce the temperature of the heater line and reduce instantaneous or long term damage to the power supply, in certain embodiments. In some cases, the pulsed DC signal(s) can include a 100 kilohertz (kHz) to 500 kHz asymmetric shaped DC pulses that have a negative voltage bias (e.g., -500 to -8000 volts) and a pulse on-time of between 10% and 95%. In some other cases, the low frequency RF signal(s) can include a 100 kilohertz (kHz) to 13.56 megahertz (MHz) signal, such as a 2 MHz RF signal.

Generally, the filter assembly 160 of the processing chamber 100 of FIG. 1 may include any number of the filter assemblies shown in FIGS. 2A through 2L. For example, each heating zone of the heater element 113 may be connected to a different filter assembly shown in FIGS. 2A through 2L. As a result the different filter assemblies may block different frequencies of DC pulse signals and/or RF signals from traveling from the heater element 113 to a power supply of the heater element 113.

An air core inductor (which may also be referred to as an air coil inductor) includes a metal coil formed around a non-magnetic core. Typically, the core includes air, but in some embodiments, the core may include a ceramic, plastic, or other non-conductive material. As a result, the coil may not be supported by a solid core (e.g., a ferrite core), but rather, air is inside the coil. The air core inductor uses self-inductance of the metal coil to store energy in a magnetic field instead of using a ferrite core or ferromagnetic core. As a result, the air core inductor does not experience magnetic saturation that would otherwise limit the inductor’s ability to efficiently and effectively filter the applied DC pulse and/or RF signals.

FIG. 2A shows an example filter assembly 160A. As seen in FIG. 2A, the filter assembly 160A includes impedance producing elements 202A and 202B and air core inductors 204A and 204B. The impedance producing elements 202A and 202B may be common mode choke filters. Each of the impedance producing elements 202A and 202B include a conductive lead 206A and a conductive lead 206B wound around a conductor (e.g., a conductive toroid shaped core). For example, first ends of the conductive leads 206A and 206B are coupled to the outputs of the power supply 165. The conductive leads 206A and 206B then wound around a conductor to form the impedance producing element 202A. From the impedance producing element 202A, the conductive leads 206A and 206B wound around another conductor to form the impedance producing element 202B. From the impedance producing element 202B, the second end, or opposing end, of the conductive lead 206A connects to the air core inductor 204A, and the second end, or opposing end, of the conductive lead 206B connects to the air core inductor 204B. The air core inductors 204A and 204B then connect to the heater in the processing chamber.

Generally, the air core inductors 204A and 204B form a filter that prevents low frequency RF signals and/or DC pulse signals (e.g., DC shaped pulses) that couple from a power electrode in the processing chamber into the heater from traveling to the power supply 165. As a result, the air core inductors 204A and 204B reduce the temperature of the heater line and reduce damage to the power supply 165. In some embodiments, the air core inductors 204A and 204B may have an inductance of between about 50 microHenries (µH) and about 200 µH, such as approximately 100 µH. Additionally, the air core inductors 204A and 204B may avoid ferrite core saturation.

In some embodiments, the filter assembly 160A includes impedance elements 208A and 208B connected to the conductive leads 206A and 206B, respectively, between the impedance producing elements 202A and 202B. Each of the impedance elements 208A and 208B may include any number of capacitors and/or inductors that are connected in series or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2B shows an example filter assembly 160B. As seen in FIG. 2B, the filter assembly 160B includes the impedance producing element 202A and the air core inductors 204A and 204B. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are coupled to the outputs of the power supply 165. The conductive leads 206A and 206B then wound around a conductor to form the impedance producing element 202A. From the impedance producing element 202A, the conductive lead 206A connects to the air core inductor 204A, and the conductive lead 206B connects to the air core inductor 204B. The air core inductors 204A and 204B then connect to the heater in the processing chamber.

Similar to the filter assembly 160A shown in FIG. 2A, the air core inductors 204A and 204B in the filter assembly 160B form a filter that prevents low frequency RF and/or pulsed DC signals (e.g., DC shaped pulses) that couple from a power electrode in the processing chamber into the heater from traveling to the power supply 165. As a result, the air core inductors 204A and 204B reduce the temperature of the heater line and reduce damage to the power supply 165. In some embodiments, the air core inductors 204A and 204B may have an inductance of between about 50 µH and about 200 µH, such as approximately 100 microHenries (µH). Additionally, the air core inductors 204A and 204B may avoid ferrite core saturation.

In some embodiments, the filter assembly 160B includes the impedance elements 208A and 208B connected to the conductive leads 206A and 206B, respectively, between the impedance producing element 202A and the air core inductors 204A and 204B. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2C shows an example filter assembly 160C. As seen in FIG. 2C, the filter assembly 160C includes the impedance producing element 202A and the air core inductors 204A, 204B, 204C, and 204D. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, the conductive lead 206A connects to the air core inductor 204A, and the conductive lead 206B connects to the air core inductor 204B. The air core inductor 204A is connected to the air core inductor 204C, and the air core inductor 204B is connected to the air core inductor 204D. The air core inductors 204C and 204D then connect to the heater in the processing chamber.

Similar to the filter assembly 160A shown in FIG. 2A, the air core inductors 204C and 204D in the filter assembly 160C form a filter that prevents low frequency RF and/or pulsed DC signals (e.g., DC shaped pulses) that couple from a power electrode in the processing chamber into the heater from traveling to the power supply 165. As a result, the air core inductors 204C and 204D reduce the temperature of the heater line and reduce damage to the power supply 165. In some embodiments, the air core inductors 204C and 204D may have an inductance of between about 50 µH and about 200 µH, such as approximately 100 µH. Additionally, the air core inductors 204C and 204D may avoid ferrite core saturation.

Additionally, the filter assembly 160C includes capacitors 210A and 210B connected in parallel with the air core inductors 204A and 204B, respectively. The capacitors 210A and 210B form filters (e.g., notch filters) with the air core inductors 204A and 204B. The filters may prevent certain frequencies of RF and/or pulsed DC signals from traveling from the heater to the power supply 165. The inductances of the air core inductors 204A and 204B and the capacitances of the capacitors 210A and 210B may be selected to target certain frequencies.

In some embodiments, the filter assembly 160C includes the impedance elements 208A and 208B connected to the conductive leads 206A and 206B, respectively, between the impedance producing element 202A and the air core inductors 204A and 204B. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2D shows an example filter assembly 160D. As seen in FIG. 2D, the filter assembly 160D includes the impedance producing element 202A and the air core inductors 204A and 204B. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, the conductive lead 206A connects to the air core inductor 204A, and the conductive lead 206B connects to the air core inductor 204B. The air core inductors 204A and 204B then connect to the heater in the processing chamber.

Additionally, the filter assembly 160D includes the capacitors 210A and 210B connected in parallel with the air core inductors 204A and 204B, respectively. The capacitors 210A and 210B form filters (e.g., notch filters) with the air core inductors 204A and 204B. The filters may prevent certain frequencies of RF and/or DC pulsed signals from traveling from the heater to the power supply 165. The inductances of the air core inductors 204A and 204B and the capacitances of the capacitors 210A and 210B may be selected to target certain frequencies.

In some embodiments, the filter assembly 160D includes the impedance elements 208A and 208B connected to the conductive leads 206A and 206B, respectively, between the impedance producing element 202A and the air core inductors 204A and 204B. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2E shows an example filter assembly 160E. As seen in FIG. 2E, the filter assembly 160E includes the impedance producing element 202A and the air core inductors 204A, 204B, 204C, and 204D. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, a second end of the conductive lead 206A connects to the air core inductor 204A, and a second end of the conductive lead 206B connects to the air core inductor 204B. The air core inductor 204A is connected to the air core inductor 204C, and the air core inductor 204B is connected to the air core inductor 204D. The air core inductors 204C and 204D then connect to the heater in the processing chamber.

Additionally, the filter assembly 160E includes capacitors 210A, 210B, 210C, and 210D. The capacitor 210A is connected in parallel with the air core inductor 204A. The capacitor 210B is connected in parallel with the air core inductor 204B. The capacitor 210C is connected in parallel with the air core inductor 204C. The capacitor 210D is connected in parallel with the air core inductor 204D. The capacitors 210A, 210B, 210C, and 210D form filters (e.g., notch filters) with the air core inductors 204A, 204B, 204C, and 204D. The filters may prevent certain frequencies of RF and/or DC pulsed signals from traveling from the heater to the power supply 165. The inductances of the air core inductors 204A, 204B, 204C, and 204D and the capacitances of the capacitors 210A, 210B, 210C, and 210D may be selected to target certain frequencies.

In some embodiments, the filter assembly 160E includes the impedance elements 208A and 208B connected to the conductive leads 206A and 206B, respectively, between the impedance producing element 202A and the air core inductors 204A and 204B. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2F shows an example filter assembly 160F. As seen in FIG. 2F, the filter assembly 160F includes the impedance producing element 202A and the air core inductors 204A and 204B. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, a second end of the conductive lead 206A connects to the air core inductor 204A, and a second end of the conductive lead 206B connects to the air core inductor 204B. The air core inductors 204A and 204B then connect to the heater in the processing chamber.

Similar to the filter assembly 160A shown in FIG. 2A, the air core inductors 204A and 204B in the filter assembly 160F form a filter that prevents low frequency RF and/or DC pulsed signals (e.g., DC shaped pulses) that couple from a power electrode in the processing chamber into the heater from traveling to the power supply 165. As a result, the air core inductors 204A and 204B reduce the temperature of the heater line and reduce damage to the power supply 165. In some embodiments, the air core inductors 204A and 204B may have an inductance of between about 50 µH and about 200 µH, such as approximately 100 µH. Additionally, the air core inductors 204A and 204B may avoid ferrite core saturation.

In some embodiments, the filter assembly 160F includes the impedance elements 208A and 208B connected to the conductive leads 206A and 206B, respectively, between the power supply 165 and the impedance producing element 202A. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2G shows an example filter assembly 160G. As seen in FIG. 2G, the filter assembly 160G includes the impedance producing element 202A and the air core inductors 204A, 204B, 204C, and 204D. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, a second end of the conductive lead 206A connects to the air core inductor 204A, and a second end of the conductive lead 206B connects to the air core inductor 204B. The air core inductor 204A is connected to the air core inductor 204C, and the air core inductor 204B is connected to the air core inductor 204D. The air core inductors 204C and 204D then connect to the heater in the processing chamber.

Similar to the filter assembly 160A shown in FIG. 2A, the air core inductors 204C and 204D in the filter assembly 160G form a filter that prevents low frequency RF and/or DC pulsed signals (e.g., DC shaped pulses) that couple from a power electrode in the processing chamber into the heater from traveling to the power supply 165. As a result, the air core inductors 204C and 204D reduce the temperature of the heater line and reduce damage to the power supply 165. In some embodiments, the air core inductors 204C and 204D may have an inductance of between about 50 µH and about 200 µH, such as approximately 100 µH. Additionally, the air core inductors 204C and 204D may avoid ferrite core saturation.

Additionally, the filter assembly 160G includes capacitors 210A and 210B connected in parallel with the air core inductors 204A and 204B, respectively. The capacitors 210A and 210B form filters (e.g., notch filters) with the air core inductors 204A and 204B. The filters may prevent certain frequencies of the RF signal and/or DC pulsed signal from traveling from the heater to the power supply 165. The inductances of the air core inductors 204A and 204B and the capacitances of the capacitors 210A and 210B may be selected to target certain frequencies.

In some embodiments, the filter assembly 160G includes the impedance elements 208A and 208B connected to the conductive leads 206A and 206B, respectively, between the power supply 165 and the impedance producing element 202A. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2H shows an example filter assembly 160H. As seen in FIG. 2H, the filter assembly 160H includes the impedance producing element 202A and the air core inductors 204A and 204B. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, a second end of the conductive lead 206A connects to the air core inductor 204A, and a second end of the conductive lead 206B connects to the air core inductor 204B. The air core inductors 204A and 204B then connect to the heater in the processing chamber.

Additionally, the filter assembly 160H includes the capacitors 210A and 210B connected in parallel with the air core inductors 204A and 204B, respectively. The capacitors 210A and 210B form filters (e.g., notch filters) with the air core inductors 204A and 204B. The filters may prevent certain frequencies of RF and/or DC pulsed signals from traveling from the heater to the power supply 165. The inductances of the air core inductors 204A and 204B and the capacitances of the capacitors 210A and 210B may be selected to target certain frequencies.

In some embodiments, the filter assembly 160H includes the impedance elements 208A and 208B connected to the conductive leads 206A and 206B, respectively, between the power supply 165 and the impedance producing element 202A. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2I shows an example filter assembly 160I. As seen in FIG. 2I, the filter assembly 160I includes the impedance producing element 202A and the air core inductors 204A, 204B, 204C, and 204D. The impedance producing element 202A may be a common mode choke filter. The impedance producing element 202A may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, a second end of the conductive lead 206A connects to the air core inductor 204A, and a second end of the conductive lead 206B connects to the air core inductor 204B. The air core inductor 204A is connected to the air core inductor 204C, and the air core inductor 204B is connected to the air core inductor 204D. The air core inductors 204C and 204D then connect to the heater in the processing chamber.

Additionally, the filter assembly 160I includes capacitors 210A, 210B, 210C, and 210D. The capacitor 210A is connected in parallel with the air core inductor 204A. The capacitor 210B is connected in parallel with the air core inductor 204B. The capacitor 210C is connected in parallel with the air core inductor 204C. The capacitor 210D is connected in parallel with the air core inductor 204D. The capacitors 210A, 210B, 210C, and 210D form filters (e.g., notch filters) with the air core inductors 204A, 204B, 204C, and 204D. The filters may prevent certain frequencies of RF and/or DC pulsed signals from traveling from the heater to the power supply 165. The inductances of the air core inductors 204A, 204B, 204C, and 204D and the capacitances of the capacitors 210A, 210B, 210C, and 210D may be selected to target certain frequencies.

In some embodiments, the filter assembly 160I includes the impedance elements 208A and 208B connected to the conductive leads 206A and 206B, respectively, between the power supply 165 and the impedance producing element 202A. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2J shows an example filter assembly 160J. As seen in FIG. 2J, the filter assembly 160J includes the impedance producing elements 202A and 202B and the air core inductors 204A, 204B, 204C, and 204D. The impedance producing elements 202A and 202B may be common mode choke filters. The impedance producing elements 202A and 202B may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, the conductive leads 206A and 206B wound around a conductor to form the impedance producing element 202B. From the impedance producing element 202B, a second end of the conductive lead 206A connects to the air core inductor 204A, and a second end of the conductive lead 206B connects to the air core inductor 204B. The air core inductor 204A is connected to the air core inductor 204C, and the air core inductor 204B is connected to the air core inductor 204D. The air core inductors 204C and 204D then connect to the heater in the processing chamber.

Similar to the filter assembly 160A shown in FIG. 2A, the air core inductors 204C and 204D in the filter assembly 160J form a filter that prevents low frequency RF and/or DC pulsed signals (e.g., DC shaped pulses) that couple from a power electrode in the processing chamber into the heater from traveling to the power supply 165. As a result, the air core inductors 204C and 204D reduce the temperature of the heater line and reduce damage to the power supply 165. In some embodiments, the air core inductors 204C and 204D may have an inductance of between about 50 µH and about 200 µH, such as approximately 100 µH. Additionally, the air core inductors 204C and 204D may avoid ferrite core saturation.

Additionally, the filter assembly 160J includes capacitors 210A and 210B connected in parallel with the air core inductors 204A and 204B, respectively. The capacitors 210A and 210B form filters (e.g., notch filters) with the air core inductors 204A and 204B. The filters may prevent certain frequencies of RF and/or DC pulsed signals from traveling from the heater to the power supply 165. The inductances of the air core inductors 204A and 204B and the capacitances of the capacitors 210A and 210B may be selected to target certain frequencies.

In some embodiments, the filter assembly 160J includes the impedance elements 208A and 208B connected to the conductive leads 206A and 206B, respectively, between the impedance producing elements 202A and 202B. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2K shows an example filter assembly 160K. As seen in FIG. 2K, the filter assembly 160K includes the impedance producing elements 202A and 202B and the air core inductors 204A and 204B. The impedance producing elements 202A and 202B may be common mode choke filters. The impedance producing elements 202A and 202B may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, the conductive leads 206A and 206B wound around a conductor to form the impedance producing element 202B. From the impedance producing element 202B, a second end of the conductive lead 206A connects to the air core inductor 204A, and a second end of the conductive lead 206B connects to the air core inductor 204B. The air core inductors 204A and 204B then connect to the heater in the processing chamber.

Similar to the filter assembly 160A shown in FIG. 2A, the air core inductors 204A and 204B in the filter assembly 160K form a filter that prevents low frequency RF and/or DC pulsed signals (e.g., DC shaped pulses) that couple from a power electrode in the processing chamber into the heater from traveling to the power supply 165. As a result, the air core inductors 204A and 204B reduce the temperature of the heater line and reduce damage to the power supply 165. In some embodiments, the air core inductors 204A and 204B may have an inductance of between about 50 µH and about 200 µH, such as approximately 100 µH. Additionally, the air core inductors 204A and 204B may avoid ferrite core saturation.

Additionally, the filter assembly 160K includes capacitors 210A and 210B connected in parallel with the air core inductors 204A and 204B, respectively. The capacitors 210A and 210B form filters (e.g., notch filters) with the air core inductors 204A and 204B. The filters may prevent certain frequencies of RF and/or DC pulsed signals from traveling from the heater to the power supply 165. The inductances of the air core inductors 204A and 204B and the capacitances of the capacitors 210A and 210B may be selected to target certain frequencies.

In some embodiments, the filter assembly 160K includes the impedance elements 208A and 208B connected to the conductive leads 206A and 206B, respectively, between the impedance producing elements 202A and 202B. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 2L shows an example filter assembly 160L. As seen in FIG. 2L, the filter assembly 160L includes the impedance producing elements 202A and 202B and the air core inductors 204A, 240B, 204C, and 204D. The impedance producing elements 202A and 202B may be common mode choke filters. The impedance producing elements 202A and 202B may include the conductive lead 206A and the conductive lead 206B wound around a conductor (e.g., a conductive toroid shaped core). For example, first ends of the conductive leads 206A and 206B are connected to the outputs of the power supply 165. The conductive leads 206A and 206B then wound around a conductor to form the impedance producing element 202A. From the impedance producing element 202A, a second end of the conductive lead 206A connects to the air core inductor 204A, and a second end of the conductive lead 206B connects to the air core inductor 204B. The air core inductor 204A is connected to the air core inductor 204C, and the air core inductor 204B is connected to the air core inductor 204D. The air core inductors 204C and 204D then connect to the heater in the processing chamber.

Additionally, the filter assembly 160L includes capacitors 210A, 210B, 210C, and 210D. The capacitor 210A is connected in parallel with the air core inductor 204A. The capacitor 210B is connected in parallel with the air core inductor 204B. The capacitor 210C is connected in parallel with the air core inductor 204C. The capacitor 210D is connected in parallel with the air core inductor 204D. The capacitors 210A, 210B, 210C, and 210D form filters (e.g., notch filters) with the air core inductors 204A, 204B, 204C, and 204D. The filters may prevent certain frequencies of RF and/or DC pulsed signals from traveling from the heater to the power supply 165. The inductances of the air core inductors 204A, 204B, 204C, and 204D and the capacitances of the capacitors 210A, 210B, 210C, and 210D may be selected to target certain frequencies.

In some embodiments, the filter assembly 160L includes the impedance elements 208A and 208B connected to the conductive leads 206A and 206B, respectively, between the impedance producing elements 202A and 202B. Each of the impedance elements 208A and 208B may include any number of capacitors and/or inductors that are connected in series and/or parallel to an electrical ground. For example, each of the impedance elements 208A and 208B may include a capacitor connected between the conductive leads 206A and 206B and electrical ground. As another example, each of the impedance elements 208A and 208B may include a capacitor and inductor connected in series between the conductive leads 206A and 206B and electrical ground.

FIG. 3 illustrates an example impedance producing element 202 of the filter assemblies of FIGS. 2A through 2L, according to one embodiment. Generally, the impedance producing element 202 is a common mode choke filter formed using the conductive leads 206 and 206B and a conductor 302. In the example of FIG. 3, the conductor 302 is a toroid shaped core (e.g., a ring or toroid). The conductive leads 206A and 206B wound around the conductor 302 to form the impedance producing element 202. In some embodiments, the conductive leads 206A and 206B are wound around the conductor 302 in opposite directions (e.g., oppositely wound conductive leads).

FIG. 4 is a flowchart of an example method 400 performed by the processing chamber 100 of FIG. 1, according to one embodiment. By performing the method 400, the processing chamber 100 uses a filter assembly to block low frequency RF and/or DC pulsed signals (e.g., DC shaped pulses) that couple from a power electrode to a heater element from traveling from the heater element to a power supply of the heater element. In this manner, the processing chamber 100 reduces the temperature of the heater line and reduces damage to the power supply.

At block 402, the processing chamber 100 provides AC power (e.g., 60 Hz AC signal) to the heater. The power supply may provide power to the heater through the filter assembly. For example, the power supply may direct an electrical signal through the filter assembly and to the heater to provide power to the heater element(s) (i.e., conductive elements 114 in FIG. 1). By providing power to the heater, the heater elements increase in temperature and heats a substrate in the processing chamber 100. During operation of the processing chamber 100, electrical signals (e.g., RF and/or DC pulsed signals) from a power electrode in the processing chamber may capacitively couple into the heater. These electrical signals may travel through the heater and towards the filter assembly.

At block 404, the processing chamber 100 filters an undesirable signal that couples through the heater element(s). For example, the filter assembly may filter out a portion of the signal (e.g., lower frequencies and harmonics) that are capacitively coupled from the power electrode into the heater element(s) so that the signal does not reach the heater power supply. The filter assembly includes one or more impedance producing elements (e.g., common mode choke filters) and two or more air core inductors that are connected to the impedance producing elements and to the heater. The air core inductors may filter out the portion of the signal that coupled from the power electrode into the heater.

In summary, the filter assembly for external circuitry, such as the heater line(s), of the processing chamber uses a hybrid filter design that includes one or more common mode choke filters and one or more filters using air core inductors. The air core inductors provide high impedance for low frequency RF and/or DC pulsed signals, such as the fundamental frequency for RF and/or DC shaped pulses and their harmonics. The common mode choke filters and the filters using air core inductors may be electrically connected to each other between a power supply and the heater in the processing chamber.

1. A filter assembly comprising:
a first impedance producing element comprising a first conductive lead and a second conductive lead wound around a first toroid shaped core, wherein a first end of the first conductive lead and a first end of the second conductive lead are coupled to outputs of an electric device;
a first air core inductor electrically connected with a second end of the first conductive lead; and
a second air core inductor electrically connected with a second end of the second conductive lead.

2. The filter assembly of claim 1, further comprising:
a third air core inductor connected in series with the first air core inductor; and
a fourth air core inductor connected in series with the second air core inductor.

3. The filter assembly of claim 1, further comprising:
a first capacitor connected in parallel with the first air core inductor; and
a second capacitor connected in parallel with the second air core inductor.

4. The filter assembly of claim 1, further comprising:
a first impedance element connected between the second end of the first conductive lead and ground; and
a second impedance element connected between the second end of the second conductive lead and ground.

5. The filter assembly of claim 1, further comprising a second impedance producing element connected to the first impedance producing element, the first air core inductor, and the second air core inductor, wherein the second impedance producing element comprises the first conductive lead and the second conductive lead wound around a second toroid shaped core.

6. The filter assembly of claim 5, further comprising a first impedance element connected to ground at a position between the first impedance producing element and the second impedance producing element.

7. The filter assembly of claim 1, wherein the first air core inductor forms a notch filter that blocks a radio frequency signal from reaching the first impedance producing element.

8. A method comprising:
directing a first electrical signal from a power supply to a heating element of a heater assembly of a processing chamber;
receiving a second electrical signal at the heating element; and
filtering, using a first air core inductor and a second air core inductor electrically connected between the heating element and the power supply, the second electrical signal to prevent a portion of the second electrical signal from reaching the power supply.

9. The method of claim 8, wherein filtering the second electrical signal further uses:
a third air core inductor connected in series with the first air core inductor; and
a fourth air core inductor connected in series with the second air core inductor.

10. The method of claim 8, wherein filtering the second electrical signal further uses:
a first capacitor connected in parallel with the first air core inductor; and
a second capacitor connected in parallel with the second air core inductor.

11. The method of claim 8, wherein directing the first electrical signal from the power supply to the heater assembly uses:
a first impedance producing element comprising a first conductive lead and a second conductive lead wound around a first toroid shaped core;
a first impedance element connected between the first conductive lead and ground; and
a second impedance element connected between the second conductive lead and ground.

12. The method of claim 11, wherein directing the first electrical signal from the power supply to the heater assembly further uses a second impedance producing element connected to the first impedance producing element, the first air core inductor, and the second air core inductor, wherein the second impedance producing element comprises the first conductive lead and the second conductive lead wound around a second toroid shaped core.

13. The method of claim 12, wherein the first impedance element is connected to the first conductive lead between the first impedance producing element and the second impedance producing element.

14. The method of claim 8, wherein the first air core inductor forms a notch filter that blocks a radio frequency signal from reaching the power supply.

15. A processing chamber comprising:
a substrate support;
an electrode within the substrate support;
a heater element of a heater assembly within the substrate support;
a filter assembly connected to the heater element, wherein the filter assembly comprises:
a first impedance producing element comprising a first conductive lead and a second conductive lead wound around a first toroid shaped core;
a first air core inductor electrically connected with the first conductive lead; and
a second air core inductor electrically connected with the second conductive lead.

16. The processing chamber of claim 15, wherein the filter assembly further comprises:
a third air core inductor connected in series with the first air core inductor; and
a fourth air core inductor connected in series with the second air core inductor.

17. The processing chamber of claim 15, wherein the filter assembly further comprises:
a first capacitor connected in parallel with the first air core inductor; and
a second capacitor connected in parallel with the second air core inductor.

18. The processing chamber of claim 15, wherein the filter assembly further comprises:
a first impedance element connected between the first conductive lead and ground; and
a second impedance element connected between the second conductive lead and ground.

19. The processing chamber of claim 15, wherein the filter assembly further comprises a second impedance producing element connected to the first impedance producing element, the first air core inductor, and the second air core inductor, wherein the second impedance producing element comprises the first conductive lead and the second conductive lead wound around a second toroid shaped core.

20. The processing chamber of claim 19, wherein the filter assembly further comprises a first impedance element connected to ground and to the first conductive lead between the first impedance producing element and the second impedance producing element.
